(19) United States
(12) Patent Application Publication
(10) Pub. No.: US 2004/0043584 A1
(43) Pub. Date: Mar. 4, 2004

(54) Semiconductor device and method of making same

(76) Inventors: Shawn G. Thomas, Tempe, AZ (US); Thomas E. Zirkle, Tempe, AZ (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/228,715

(22) Filed: Aug. 27, 2002

(51) Int. Cl. H01L 21/336; H01L 21/36; H01L 21/20

(52) U.S. Cl. 438/507

(57) ABSTRACT

In one example embodiment, an integrated semiconductor circuit (400) is provided. The integrated circuit (400) comprises a substrate (430) comprising a first material and a first electronic device (455) comprising a first depressed region (415) within the substrate (430) and a set of first device contact locations (475) in a contact level (300). The integrated circuit (400) further comprises a second electronic device 450 comprising a set of second device contact locations (451) in the contact level (300) and a second material (420) in the first depressed (415) region having a lattice mismatch with the first material.

### BACKGROUND OF THE INVENTION

This invention generally relates to semiconductor devices and their construction.

Germanium (Ge) has become an alternative to Silicon for various semiconductor devices. Because certain wavelengths of light (1.3-1.55 micrometers) are recognized by Ge, but not Silicon, Ge is often used in photodetectors. Ge also has a high intrinsic mobility that allows transistors to operate at high speeds. Despite these advantages, Silicon is still widely used in the semiconductor industry, and there are many existing Silicon manufacturing tools. Therefore, it is advantageous to integrate Germanium onto a Silicon substrate. However, there is a lattice mismatch between Ge and Si that causes strain and limits the thickness of a pseudomorphic Ge layer that can be formed on a Si substrate without dislocations being formed to relieve the strain. This problem is not unique to Ge and Si; it occurs when integrating many lattice-mismatched materials.

FIG. 1 illustrates that dislocations 110 form near the interface 160 of a mismatched epitaxial layer 120 and substrate 130 to relieve the misfit strain. Dislocations 110 also have vertical components 115, which are known as “threading dislocations,” that terminate at the wafer surface 140, the edge of the wafer, or on another dislocation. A substantially dislocation-free active region of the semiconductor layer is preferred, because dislocations cause recombination and leakage that degrade performance in devices (e.g., optical devices and transistors).

Some techniques that have been suggested to grow mismatched materials include forming mesas on a substrate, growing a mismatched material on the mesas, and forming a device or an integrated circuit in the mismatched material on the mesas (see, e.g., U.S. Pat. Nos. 5,285,086 and 5,158,907). The dislocations formed at the interface between the substrate material and the mismatched material terminate on the sides of the mesa. Side-termination occurs because, for any particular misfit between two lattice structures, there is a “guide plane” that has an angle limiting the rate at which a dislocation rises. If the height of the mismatched material grown on the top of the mesa is tall enough, all of the dislocations will terminate in the sides of the mismatched material, leaving a dislocation-free area in the top of the mismatched material in which a circuit device or integrated circuit can be formed. However, there is a problem.

The device or integrated circuit on the top of the mesa needs to be connected to other devices or integrated circuits that are not on the mesa. In the '086 and '907 patents, a special connection is described between the device or integrated circuit on the mesa and a separate device or integrated circuit in the substrate. The '086 and '907 patents also suggest growing mismatched material between the mesas and forming connections between vertically-separated integrated circuits or devices, one located on the mesa and another in the mismatched material in between the mesas. However, such a practice still results in a significant vertical distance between active regions; and traditional connection processes cannot be used to form the interconnections between an integrated circuit on a mesa and a separate device or integrated circuit located between mesas. Many common interconnection processes for forming integrated circuits require deposition of dielectric and planarization before interconnection. With a significant vertical distance between active devices, the planarization is more difficult or impossible.

Use of regions such as the mesas described in the '907 and '086 patents also results in difficulties constructing devices having active regions in both the mismatched materials and active regions in substrate materials. Forming mesas of mismatched material also inhibits the ability to form single integrated circuits from devices in the substrate and devices having active regions in the mismatched material, again due to the inability to apply a single interconnection step.

### BRIEF DESCRIPTION OF THE FIGURES

FIG. 1 is a side view of dislocations formed in a layer of mismatched material in the prior art.

FIG. 2 is a side view of dislocations terminating in the side of a trench according to an example embodiment of the invention.

FIG. 3. is a side view of an integrated circuit according to an example embodiment of the present invention.

FIG. 4 is a side view of an integrated circuit according to an example embodiment of the present invention.

FIG. 5 is a side view of a trench with a liner in a substrate according to an example embodiment of the invention.

FIG. 6 is a side view of an integrated circuit according to an example embodiment of the present invention.

FIG. 7 is a side view of a bipolar transistor (BT) of an example embodiment of the present invention.

FIG. 8 is a side view of a MOSFET of an example embodiment of the present invention.

FIGS. 9-18 show a series of side views illustrating example embodiments of making an integrated circuit according to the present invention.

### DETAILED DESCRIPTION OF EXAMPLE EMBODIMENTS OF THE PRESENT INVENTION

There is a need for integrated circuits (and methods of making them) having multiple electronic devices, wherein at least one device includes materials having a lattice mismatch and an active region in a substantially dislocation-free area, and wherein contacts for the devices can be interconnected with traditional methods (e.g., application of dielectric, planarization, and application of metalization). There is also a need for specific devices of lattice mismatched material having an active region in substantially dislocation-free areas suitable for integration with other devices on a common substrate.

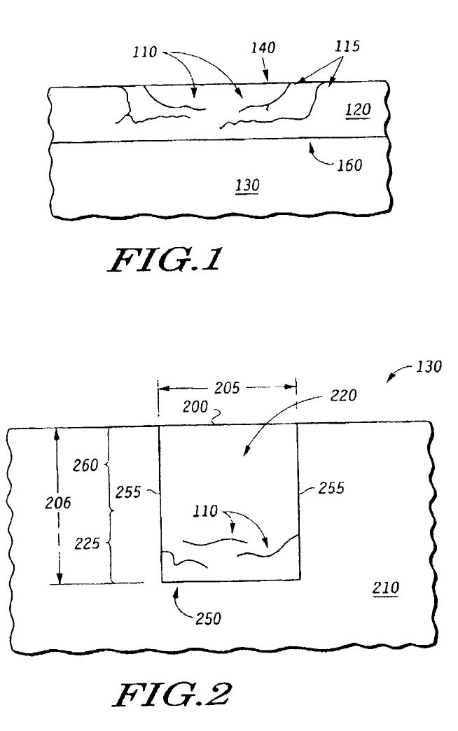

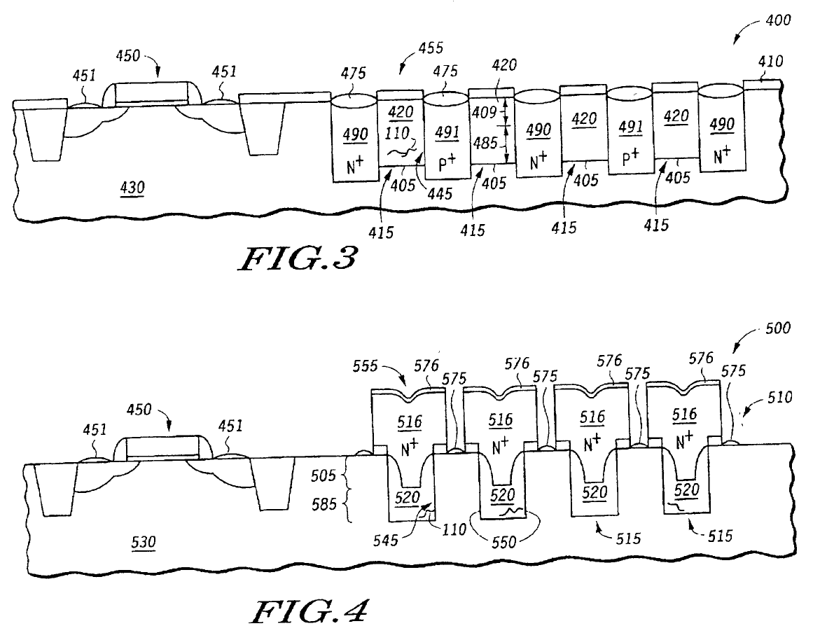

FIG. 2 illustrates a depressed region 200 (for example, a trench) in a substrate 130 according to various example embodiments of the invention. The trench 200 is filled with a material 220 that is lattice mismatched at the interface 250 with the material 210 of the substrate 130. Dislocations 110 form in a dislocation region 225 of a material 220 near the interface 250 between the material 210 and the substrate 130. However, if the dislocations 110 terminate in the side 255 of the trench 200, the upper area 260 of the material 220 will be substantially dislocation-free. Limiting the width 205 of the depressed region 200 forces the dislocations 110 to propagate to the sides 255 prior to forming threading dislocations 115 (FIG. 1). In this way, dislocations 110 are confined to the dislocation region 225 of the trench 200.

Depending on the thickness of dislocation-free upper area 260 needed for a particular device, the width 205 and depth 206 of the depressed region 200 are chosen on a case-by-case basis. For example, the glide plane in Ge, which limits the rate at which dislocations rise, has an angle of 54° from a Silicon substrate. Therefore, the ratio of the width 205 to the depth 206 of depressed region 200 is dependant upon the glide plane angle of the particular material and its crystal structure. That angle determines what width-to-height ratio is small enough to allow for a dislocation region 225 and a sufficiently thick, substantially dislocation-free area 260, where a desired active portion of a device resides. For the majority of electronic devices and materials used, the depressed region 200 has an aspect ratio greater than 1. Furthermore, while FIG. 2 illustrates a trench-shaped depressed region 200, in alternate embodiments (including those discussed below), the depressed region 200 comprises a rounded, elliptical, hemispherical, or any other shape that will occur to those of ordinary skill in the art.

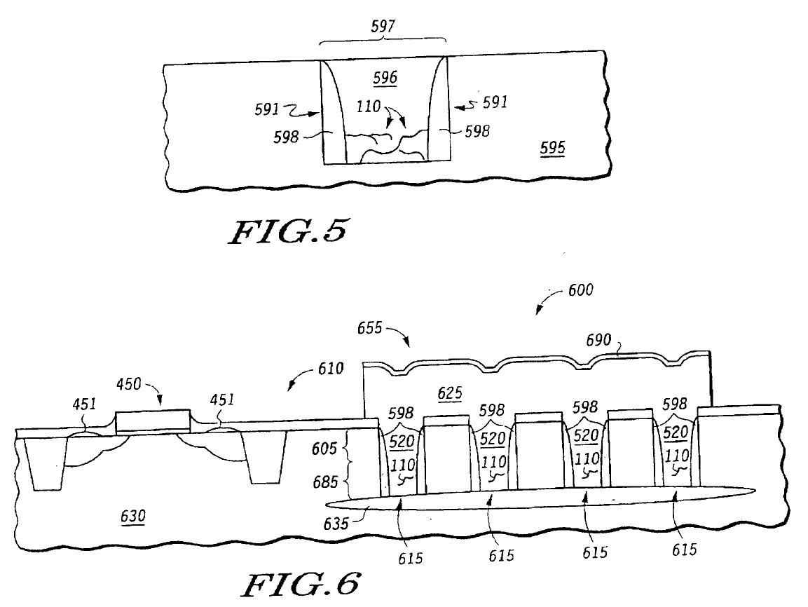

FIG. 3 illustrates various example embodiments of the present invention in which an integrated circuit 400 includes a transistor 450 and a photodetector 455. In the illustrated example, transistor 450 is illustrated as a MOSFET, although other transistor types (e.g., MESFET, BJT) and other device types are also acceptable in alternative embodiments. Interconnections between transistor 450 and photodetector 455 are not shown for simplicity. Transistor 450 and transistor contacts 451 reside on a substrate 430, which includes a first material (e.g., Silicon). The substrate 430 also includes a plurality of trenches 415 substantially filled with a second material 420 (for example, Germanium) that terminates in trenches 415.

On either side of the trenches 415 are doped regions 490 and 491, alternately doped n+ and p+. A dislocation termination area 485 exists near the interface 405 of the trenches 415 and substrate 430 (indicated in the illustration in only one of the trenches 415 for simplicity, but occurring in each trench 415). Dislocations 110 form in the dislocation termination area 485 and terminate into the sides 445 of the trenches 415. This leaves a substantially dislocation-free area 409 of the Ge trenches 415 available for an active device portion of the photodetector 455. Due to the termination of second material 420 in the trenches 415, contacts 475 of the photodetector and transistor contacts 451 are in a same contact level, making the photodetector 455 and transistor 450 suitable for integration with each other.

As used herein the term “contact level” includes a level in which contacts for devices are capable of being interconnected by a common application of metalization, making them suitable for integration on a common substrate. Further, reference to the second material “termination” in the trench 415, is not to be viewed as an absolute absence of the second material above the trench 415. As used in this document, the termination of the material “in the trench” distinguishes from the formation of significant amounts of the second material above the trench whereby significant dislocations at the surface of the substrate would form or a significant vertical displacement between the top of the second material and the substrate surface would prevent interconnection of devices with a common metalization process.

Referring still to FIG. 3, a typical protect layer 410 is also provided, as are typical dielectric and metalization layers (not shown for simplicity); and, in various embodiments, the substrate 430 includes Silicon, Gallium Arsenide, InP, SOI (Silicon-On-Insulator), or any other semiconductor material suitable as a substrate. Further, the material 420 in the trench 415 includes Germanium, SiGe, or any suitable material 420 that is mismatched from the substrate 430.

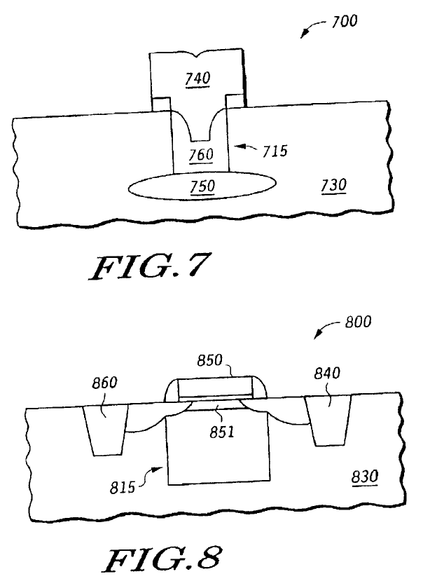

FIG. 4 illustrates another example embodiment of an integrated circuit 500 including a transistor 450 and photodetector 555. Transistor 450 and its contacts 451 reside on substrate 530 (e.g., Silicon), which includes a plurality of trenches 515 that are partially filled with a mismatched material 520 (e.g., Germanium). As with the previous integrated circuit 400 (FIG. 3), the vast majority of dislocations 110 forming in the dislocation termination area 585 terminate into the lower portion of sides 545 of the trench 515 and do not rise to the substantially dislocation-free area 505. A top area 516 includes an n+ doped region of the substrate material (e.g., Silicon). It should be noted that FIG. 4 is not drawn to scale, and the n+ doped regions 516, the contacts 575 and 576, the transistor 450, and contacts 451, are in the same contact level (again due to the termination in trench 515 of the mismatched material 520 on the sides 545). In operation, light enters through contact 576 and n+ doped regions 516 to generate flow of electrons or holes that are amplified, upon application of interconnections (not shown), by the transistor 450, as will occur to those of ordinary skill without further elaboration.

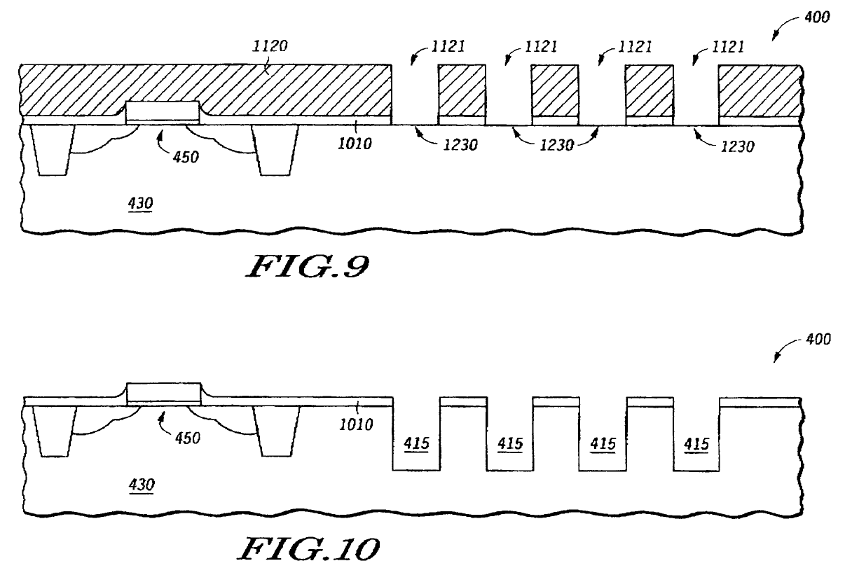

FIG. 5 illustrates a further example embodiment, in which a depressed region 597 of a substrate 595 (for example, Silicon) includes a mismatched material 596 (e.g., Germanium), and between the sides 591 of the depressed region 597 and the mismatched material 596 are liners 598, which further prevent continuation of dislocations 110. In other words, the dislocations are “pinned.” In various embodiments, the liner 598 includes a material with a random-oriented structure (for example, amorphous or polycrystalline). In alternate embodiments, the liners 598 comprise Silicon Dioxide, Silicon Nitride, Oxynitride, amorphous Si, Strontium Titanate (“STO”), complex oxides, or any other suitable random-oriented structure that will prevent the dislocations 110 from continuing into the sides 591 of the substrate 595. In the illustrated embodiment, liners 598 are grown as one mass in depressed region 597 and then etched to allow contact between mismatched material 596 and substrate 595. In some alternative examples, liner 598 remains between the bottom of material 596 and substrate 595.

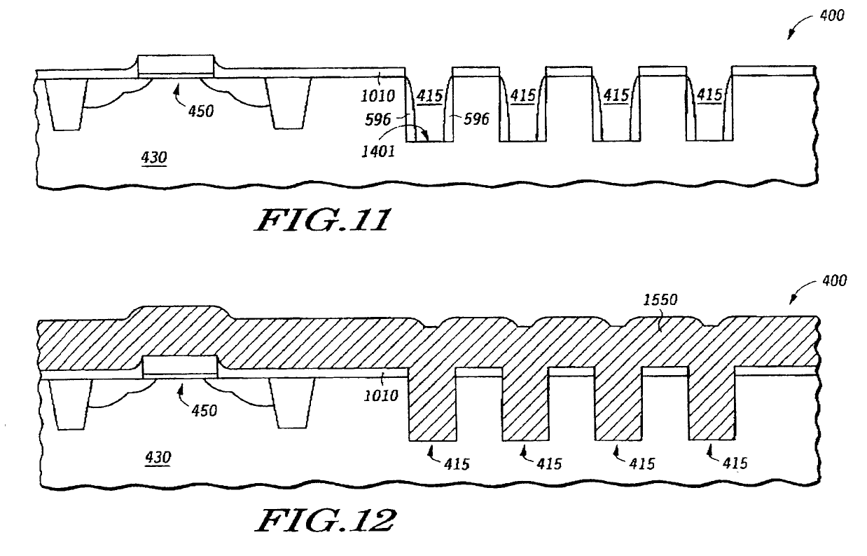

FIG. 6 illustrates an example embodiment of an integrated circuit 600 employing the liners 598 such as those described in FIG. 5. The integrated circuit 600 includes a transistor 450 and a photodetector 655. The substrate 630 includes a plurality of trenches 615 filled with a mismatched material 520 that terminates in trench 615. Below the trench 615 is a p+ doped region 635. On either side of the trench 615, is a liner 598 including, for example, Silicon Dioxide. In the dislocation termination area 685, the dislocations 110 terminate into the liner 598, leaving the dislocation-free areas 605 of the trenches 515 substantially dislocation-free. Above the trenches 615 is an n+ doped region 625 of Silicon. In operation, light enters from above the n+ doped region 625. Transistor 450, contacts 451, and contacts 690 over the n+ doped region 625, are in the same contact level (as with FIG. 5, FIG. 6 is not drawn to scale).

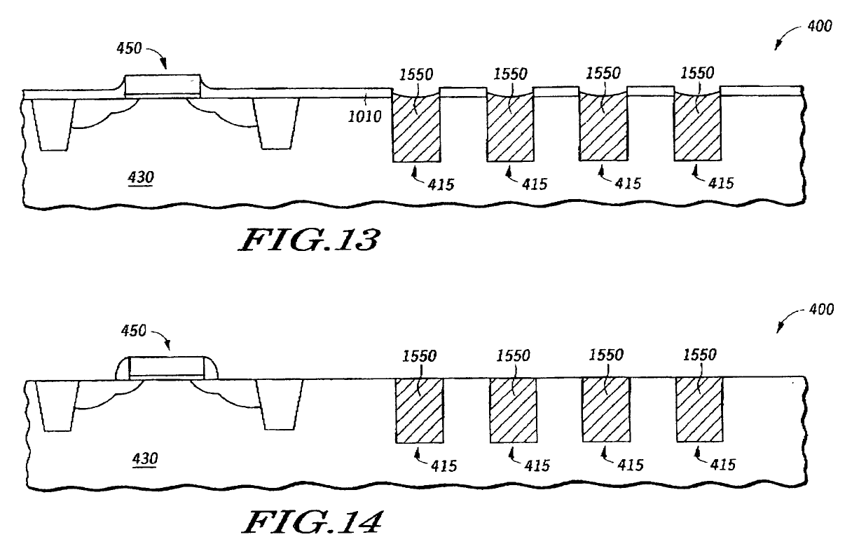

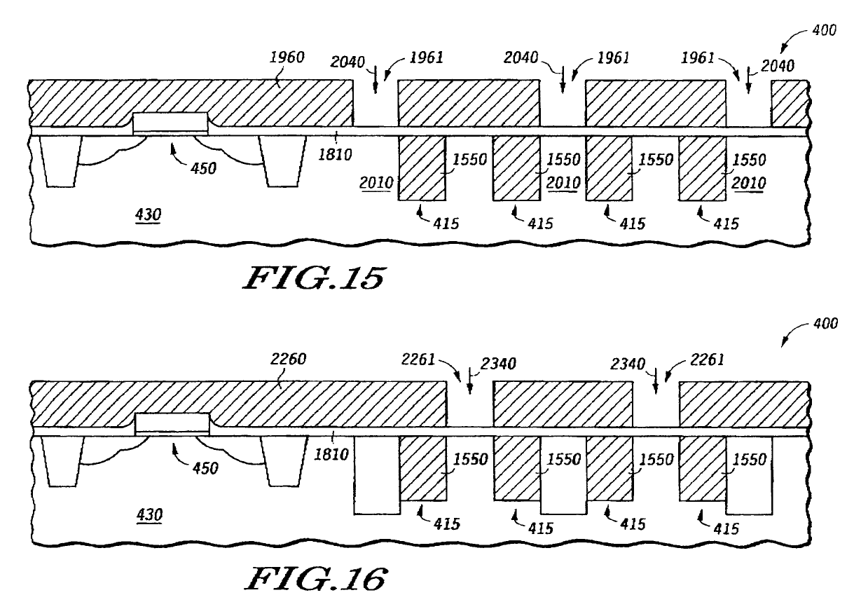

FIGS. 7 and 8 illustrate some further examples of devices according to the present invention. FIG. 7 illustrates a bipolar transistor 700 in which substrate 730 includes a trench 715 substantially filled with a material 760 (e.g., doped Germanium), which is mismatched from the substrate material 730 (e.g., Silicon). N+ doped poly-silicon forms an emitter 740 and the bottom portion 750 of the mismatched material 760 is doped to form a collector 750. The material 760 of the trench 715 then forms the base of the transistor 700. In some embodiments, a liner 598 (FIG. 5) of random-oriented structure material (e.g., SiO2) resides between the material 760 and substrate 730.

FIG. 8 illustrates a MOSFET 800 in which substrate 830 (for example, Silicon) includes trench 815 that includes, for example, Germanium. A source 860 and drain 840 are located on either side of the trench 815. Above the trench 815 is a gate 850. The channel 851 of the MOSFET 800 includes at least a portion of the Germanium trench 815. In an alternative embodiment, trench 815 is lined (FIG. 5) with a random-oriented structure material.

Both FIGS. 7 and 8 illustrate examples of a transistor device having an input component (e.g., a source or emitter) an output component (e.g., a drain or collector), and a gain component (e.g., a base or channel). The gain component is located in the substantially dislocation-free area.

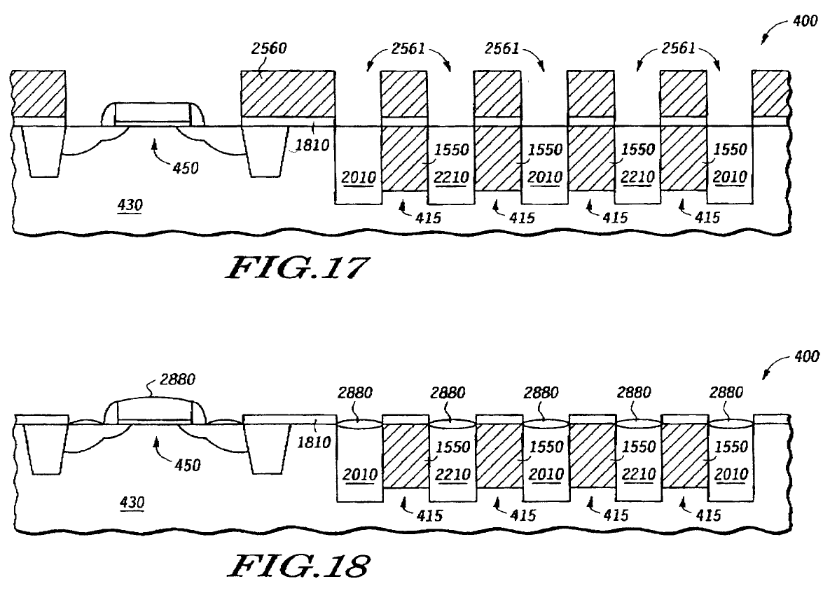

FIGS. 9-18 illustrate a series of step-by-step views of example embodiments of making an integrated circuit. Specifically, the steps of making the integrated circuit 400 of FIG. 3 are discussed in detail; however, in alternate embodiments, the devices, the materials, the design, and the steps, will vary without the need for further elaboration.

FIG. 9 shows a MOSFET 450 on a Silicon substrate 430 formed, for example, in a conventional manner. A protect layer 1010 is deposited over the MOSFET 450 and substrate 430. In various embodiments, the protect layer 1010 includes Silicon Nitride, TEOS, oxide, or any other hard mass useful as a protect layer, deposited, for example, by chemical vapor deposition (CVD), molecular beam epitaxy (MBE), or any other method. A photoresist mask 1120 includes openings 1121 to form a trench, and the protect layer 1010 is etched within openings 1121 creating regions 1230 of the substrate 430 using, for example, wet etches (e.g., potassium hydroxide (KOH)), dry etches (e.g., a standard reactive ion etching process), or any other etching that will occur to those of ordinary skill.

As seen in FIG. 10, the photoresist is stripped, and the device 400 is cleaned. Trenches 415 are etched in the substrate 430 at the locations of the exposed regions 1230 using wet etches, dry etches, or any other etching that will occur to those of ordinary skill. In various embodiments (e.g., FIG. 11), a liner material 596 of random-oriented structure (e.g., SiO2) is then deposited (e.g., by conventional techniques) within the trench 415. Depending on design considerations, in some embodiments, liner material 596 is etched, exposing the substrate 430 at the bottom 1401 of trench 415.

FIG. 12 illustrates non-selective deposition of undoped Germanium 1550 over the substrate 430, MOSFET 450, and protect layer 1010 (using, for example molecular beam epitaxy, chemical vapor deposition (CVD), low pressure CVD, rapid thermal CVD, ultrahigh vacuum CVD, atmospheric pressure CVD, low energy plasma CVD, or any other non-selective deposition technique). The Germanium 1550 substantially fills the trenches 415. Non-selective deposition allows use of standard tooling; however, in alternate embodiments, selective deposition processes are used to fill only the trenches 415 to allow for greater control of the Ge layer 1550. In some embodiments, the selective deposition uses a gas precursor during CVD (e.g., Chlorine). In alternative embodiments, gas precursors during MBE (molecular beam epitaxy) are used.

In further embodiments, trenches 415 comprise other material (e.g., Gallium Arsenide, Indium Phosphide, Silicon Germanium, and Silicon Carbide) suitable for the desired device to be built.

In FIG. 13, presuming a non-selective deposition of Ge 1550, planarization is used to remove the excess Germanium 1550 above the device 400 and leaves the trenches 415 substantially filled with Germanium 1550 terminating in trenches 415. In various examples, various planarization techniques are used, including: reactive ion etching, chemical mechanical polishing (“CMP”), or any other method of planarization. It should be noted that MOSFET 450, in fact, has a much lower profile than that shown; the figures are not drawn to scale. Further, much of the planarization is chemically-based, and the protect layer 1010 further prevents damage to the MOSFET 450. In the illustrated example, the Germanium 1550 terminates in the trenches 415, although some small residual amount of Germanium 1550 may cling to the protect layer 1010 at the edges. In FIG. 14, protect layer 1010 is stripped, and Germanium 1550 is seen terminating in trenches 415.

Then, as seen in FIG. 15, another protect layer 1810 is deposited over the transistor 450, Ge 1550, the MOSFET 450, and substrate 430. Another photoresist mask 1960 having openings 1961 defines regions 2010 to be doped. Ion implant 2040 is used, in some examples, to n+ dope the region 2010 using photoresist mask 1960 as an implant mask.

The photoresist 1960 is stripped, and the device 400 is cleaned, leaving a protect layer 1810 over the substrate 430, trenches 415, and n+doped regions 2010. As seen in FIG. 16, another standard photoresist mask 2260, having openings 2261, defines regions 2210 to be ion implanted by p+ ion implant 2340.

In FIG. 17, the photoresist mask 2260 is stripped, the device 400 is cleaned, and the device 400 now has Ge filled trenches 415 with an n+ doped region 2010 on one side of the trench 415 and a p+ doped region 2210 on the other side of the trench 415. Activation RTA (rapid thermal annealing) is then performed to activate the doping. A further standard photoresist mask 2560 is formed with openings 2561, and the protect layer 1810 is etched within openings 2561 to expose n+ doped regions 2010 and p+ doped regions 2210.

FIG. 18 shows the photoresist mask 2560 stripped and the device 400 cleaned. Another RTA is used to activate the dopant, and contact points 2880 (e.g., silicide, etc.) are applied to the device. Further common processing steps (e.g., deposition of dielectric, planarization, and metalization application) are then used to form interconnections (not shown) to complete integrated circuit 400.

In various alternate embodiments, various combinations of the techniques just described are used to make the various devices discussed above, as well as other devices, according to the present invention. For example, in the example embodiments of FIGS. 4 and 7, after substantially filling trenches 515, mismatched material 520 is etched to allow application of n+ doped Silicon in top area 516 (by any of a variety of methods that will occur to those of skill in the art without further elaboration). Collector 750 is formed, in some example embodiments, by ion implantation. Likewise dopants and devices have been given as either “p” or “n,” although they are reversed in many other examples. Further, various amounts and gradations of doping of the various materials used in the various embodiments are appropriate, depending on the specific devices to be made and their desired performance characteristics.

The example embodiments of the present invention have been described with a certain degree of particularity; however, many changes may be made in the details without departing from the scope of the invention. It is understood that the invention is not limited to the embodiments set forth herein, but is to be limited only by the scope of the attached claims, including the full range of equivalency to which each is entitled.

We claim:

1. An integrated semiconductor circuit comprising:
a substrate comprising a first material;
a first semiconductor device comprising the first material and a set of first device contact locations in a contact level; and
a second semiconductor device comprising a second material in a depressed region in the substrate and further comprising a set of second device contact locations in the contact level;
wherein the second material in the depressed region has a lattice mismatch with the first material.

2. The integrated semiconductor circuit of claim 1, wherein the second material comprises at least one dislocation termination area of the depressed region and includes a substantially dislocation-free area.

3. The integrated semiconductor circuit of claim 1, wherein the depressed region comprises a trench having at least two sides and a bottom.

4. The integrated semiconductor circuit of claim 3, wherein a depressed region liner resides on the at least two sides of the trench.

5. The integrated semiconductor circuit of claim 1, wherein the first material comprises Silicon and the second material comprises Germanium.

6. The integrated semiconductor circuit of claim 1 wherein the second material terminates in the depressed region.

7. The integrated semiconductor circuit of claim 1 wherein the second semiconductor device comprises a first active region located in the second material and a second active region located in the first material.

8. The integrated semiconductor circuit of claim 1, wherein all active regions of the first semiconductor device comprises the first material.

9. The integrated semiconductor circuit of claim 1, wherein the second semiconductor device comprises a photodetector.

10. The integrated semiconductor circuit of claim 1, wherein the second semiconductor device comprises a diode.

11. The integrated semiconductor circuit of claim 1, wherein the second semiconductor device comprises a transistor.

12. A transistor comprising:
an input component,
an output component,
a gain component in a depressed region in a substrate,
wherein the substrate comprises a first material having a first lattice structure and the gain component comprises a second material having a second lattice structure,
wherein there is a lattice mismatch between the first and the second lattice structures, and
wherein the gain component comprises a substantially dislocation-free area of the depressed region.

13. The transistor of claim 12, wherein the input component comprises an emitter, the output component comprises a collector, and the gain component comprises a base.

14. The transistor of claim 12, wherein the input component comprises a source, the output component comprises a drain, and the gain component comprises a channel, and further comprising a gate in electrical communication with the channel.

15. The transistor of claim 12 wherein at least one of the input or the output components comprises the first material.

16. The transistor of claim 15 wherein the at least one of the input or the output components is substantially horizontally oriented with respect to the depressed region.

17. The transistor of claim 15 wherein the at least one of the input or the output components is substantially vertically oriented with respect to the depressed region.

18. The transistor of claim 12, comprising a liner between at least a portion of the first material and at least a portion of the second material.

19. The transistor of claim 12 wherein the first material comprises Silicon and the second material comprises Germanium.

20. A photodetector comprising:
a first component comprising a first semiconductor material having a first lattice structure,
a second component comprising a second semiconductor material in a depressed region in a substrate,
wherein the second semiconductor material has a second lattice structure,
wherein there is a lattice mismatch between the first lattice structure and the second lattice structure, and
wherein the depressed region comprises a substantially dislocation-free area.

21. The photodetector of claim 20, wherein the first component is substantially horizontally positioned with respect to the second component.

22. The photodetector of claim 20, wherein the first component is substantially vertically positioned with respect to the second component.

23. The photodetector of claim 20, further comprising a liner in the depressed region.

24. The photodetector of claim 20, wherein the substrate comprises the first material.

25. The photodetector of claim 16, wherein the first semiconductor material comprises Silicon and the second semiconductor material comprises Germanium.

26. A method of making a semiconductor device, the method comprising:
creating a depressed region through a surface of a substrate wherein the substrate comprises a first material;
forming a second material within the depressed region wherein at least one dislocation terminates in a dislocation area of the second material, wherein there is a substantially dislocation-free area of the second material near the surface, and wherein the second material terminates substantially at the level of the surface;
forming at least one device component comprising the first material; and
forming at least a further device component wherein an active region of the further device component comprises the substantially dislocation-free area of the second material.

27. A method as in claim 26, wherein the forming at least one device component and the forming at least a further device component comprises forming device components in a substantially horizontal relation to each other.

28. A method as in claim 26, wherein the forming at least one device component and the forming at least a further device component comprises forming device components in a substantially vertical relation to each other.

29. The method of claim 26, wherein:
the creating comprises creating a plurality of depressed regions through the surface of the substrate, and
the forming a second material comprises forming the second material in the plurality of depressed regions.

30. The method of claim 26, further comprising applying a liner in the depressed region before forming the second material.

31. The method of claim 26 wherein the forming a second material further comprises deposition of the second material and termination of the second material in the depressed region.

32. The method of claim 31, wherein the forming the second material comprises selective deposition.

33. The method of claim 31, wherein the forming the second material comprises non-selective deposition followed by planarization.

34. The method of claim 26 wherein the first material comprises Silicon and the second material comprises Germanium.
